(19) United States
(12) Patent Application Publication
(10) Pub. No.: US 2002/0070446 A1
(43) Pub. Date: Jun. 13, 2002

(54) Semiconductor device and method for the production thereof

(76) Inventors: Michio Horiuchi, Nagano-shi (JP); Takashi Kurihara, Nagano-shi (JP)

Correspondence Address: Paul & Paul, 2900 Two Thousand Market Street, Philadelphia, PA, 19103, US

(21) Appl. No.: 10/012,778

(22) Filed: Dec. 10, 2001

(30) Foreign Application Priority Data
Dec. 13, 2000 (JP) 2000-379147

(51) Int. Cl. H01L 23/34

(52) U.S. Cl. 257/723

(57) ABSTRACT

Semiconductor device comprising a substrate composed of a resin material, semiconductor elements mounted at predetermined positions on the substrate and external connection terminals electrically connected with the semiconductor elements. The semiconductor elements and the external connection terminals are embedded in the substrate and electrically connected to each other through wires within the substrate while, at the same, time exposing the reverse surface of the semiconductor elements and the terminal surface of the external connection terminals to the same surface side of the substrate.

### BACKGROUND OF THE INVENTION

1. Field of the Invention

The present invention relates to a semiconductor device and, more particularly, to a semiconductor device that can be packaged with high density, and three-dimensionally, without using an expensive substrate or a sophisticated technique. The present invention also relates to a method of producing the semiconductor device described above.

2. Description of the Related Art

Currently, various semiconductor devices each having semiconductor elements (hereinafter sometimes referred to as “semiconductor chips”) mounted thereon have been proposed and the packages thereof have been increased in density, three-dimensionally. Further, in order to reduce the thickness, the semiconductor device has been improved in such a manner that each semiconductor element is embedded in the substrate or a space for accommodating the semiconductor elements is formed in a part of the substrate. For example, in view of the fact that the number of the terminals of the semiconductor chips mounted on the semiconductor device has increased with the increased function of the semiconductor device, a method is employed in which the electrode terminals are formed in an area array on the electrode terminal forming surface of each semiconductor chip, after which each semiconductor chip is mounted on a wiring board by flip chip connection. In flip chip connection, the bumps formed on the electrode terminals of the semiconductor elements are coupled to the pads of the wiring board thereby to connect the electrode terminals of the semiconductor elements and the external connection terminals (bumps) of the wiring board electrically to each other. Also, the current trend is toward the employment of what is called a “built-up method” in which a plurality of wiring layers and insulating layers are stacked as a wiring board.

FIG. 1 is a sectional view showing an example of a conventional semiconductor device. In the case of the semiconductor device 50 shown, a semiconductor chip 55 with electrode terminals (bumps) 53 formed in an area array is mounted on a circuit board 51. Built-up layers 59 are formed on each surface of the circuit board 51, and external connection terminals (bumps) 52 are formed on one surface (the surface lacking the semiconductor chips 55) of the circuit board 51. The semiconductor chip 55 is connected electrically to a wiring pattern (not shown) formed on the built-up layers 59 through the electrode terminals 53, on the one hand, and to the external connection terminals 52 through vias (not shown) formed on the circuit board 51. Also, a plurality of the built-up layers 59 are formed by being stacked (a stack structure of two built-up layers 59 is shown in the drawing to facilitate the explanation) in order to form a wiring pattern for electrically connecting the electrode terminals 53 of the semiconductor chip 55 and the external connection terminals 52 to each other. Further, the circuit board 51 and the semiconductor chip 10 thereon are sealed with an insulating resin material 54.

The semiconductor device shown in FIG. 1 can be generally produced by forming the built-up layers normally, using a base member of such an insulative resin material as epoxy resin or polyimide resin, and forming a wiring of a predetermined pattern on the base member on the one hand while at the same time stacking as many built-up layers as required by connecting the wiring, electrically, between the built-up layers on the other hand. The semiconductor device of this type, though suitable for realizing high-density wiring, has the disadvantages of a complicated fabrication process and an increased fabrication cost. Further, the narrow space between the wirings causes crosstalk, thereby leading to the problem of a deteriorated device reliability and a low fabrication yield.

As a solution to this problem, the present inventors have developed a semiconductor device as disclosed in Japanese Unexamined Patent Publication (Kokai) No. 11-163217. This semiconductor device 60, as shown in FIG. 2, is so configured that a semiconductor chip 65 with electrode terminals (not shown) formed in an area array thereon is mounted on one surface of a circuit board 61 with the electrode terminal forming surface thereof directed outward, on the one hand, and bonding pads 63 are formed in an area array on one surface (except for the area occupied by the semiconductor chip 65) of the circuit board 61. Also, the electrode terminals of the semiconductor chip 65 and the bonding pads 63 are electrically connected to each other through bonding wires 66 covered with an insulating film for electrically insulating the conductive wires. Further, on the other surface (the surface having no semiconductor chip 65 mounted thereon) of the circuit board 61, the external connection terminals 62 formed in an area array pattern and the bonding pads 63 are electrically connected to each other by conductive portions 67 formed through the circuit board 61 in the thickness thereof. Furthermore, the bonded portions between the electrode terminals and the bonding wires 66 and the bonded portions between the bonding wires 66 and the bonding pads 63 including the neighborhood of the particular bonded portions are covered with an insulating film 68 having an electrical insulation characteristic. Also, one surface of the circuit board 61 including the semiconductor chip 65 and the bonding wires 66 is sealed with a conductive resin material 64. By the way, the connection between the conductive portions 67 and the external connection terminals 62 is established through lands 69, respectively, formed on the end surface of each of the conductive portions 67.

In the semiconductor device shown in FIG. 2, the electrode terminals of the semiconductor chip arranged in an area array pattern and the bonding pads of the circuit board are connected to each other by wires covered with an insulating film, and therefore the configuration of the circuit board is simplified while making it possible to facilitate the fabrication and to improve the yield at the same time. Also, in view of the fact that the wiring length required for constructing the semiconductor device can be reduced, a semiconductor chip having superior electric characteristics can be provided.

To satisfy various current requirements of a semiconductor device, however, it is desirable to add further improvements to the illustrated semiconductor device. Specifically, the semiconductor device employing the wire bonding method for interconnection of the terminals may be damaged at the time of bonding depending on the semiconductor chip involved. Further, considering the situation of the semiconductor device manufacturers, it is desirable to provide a circuit board of such a type that the semiconductor chip can be easily mounted subsequently.

On the other hand, the use has also increased of a semiconductor device constituting a thin package, i.e. a TCP (tape carrier package) which is readily adapted for an increased number of pins, a reduced pitch of the connection terminals and a smaller thickness and a smaller size of the device as a whole. Typically, the TCP can be fabricated according to the TAB method in which a copper foil, after being attached on a base member (normally, a resin film) in the form of a tape having a predetermined pattern of openings, is patterned by etching thereby to form predetermined copper leads. In the next step, a semiconductor chip is set in position and held in the opening of the base member, and the connection terminals of the semiconductor chips are connected with the corresponding copper leads, after which a part of the copper leads and the semiconductor chip are sealed with the resin, thereby completing a semiconductor package. After producing a multiplicity of semiconductor packages by repeating this process, each semiconductor package is cut off. In this way, a semiconductor device having a semiconductor chip mounted in the opening is completed.

However, the reduction in the thickness of this semiconductor device has a limit. Specifically, the semiconductor chip is mounted on the base member dependencing on the copper leads, and therefore the thickness of the copper lead, the base member and the whole device is required to be increased at least to some degree to secure the strength. If a resin sealed portion is resorted to for securing the strength, it is necessary to fill the resin to a great thickness which departs from the trend toward a smaller thickness. Also, in the case of the semiconductor device of this type, different chips have different thickness and the individual mounting heights are also varied, resulting in varied heights of the semiconductor devices. It is therefore difficult to conduct an electrical test collectively for performance evaluation before cutting off the semiconductor packages.

### SUMMARY OF THE INVENTION

Accordingly, an object of the present invention is to provide a semiconductor device three-dimensionally packaged at high density without using an expensive substrate or a sophisticated fabrication technique.

Another object of the present invention is to provide a semiconductor device having a reduced and uniform mounting height of the semiconductor elements, while at the same time improving the production yield and securing a uniform height of the semiconductor devices, thereby making it possible to conduct an electrical test collectively.

Still another object of the present invention is to provide a semiconductor device in which the reliability of the internal connections of the substrate and the reliability the package are so high that crosstalk can be prevented, the internal impedance of the substrate can be matched easily, and the production can be carried out in a short time and at a low cost through a simplified process.

Yet another object of the present invention is to provide a semiconductor device having a high design latitude, in which a test can be conducted during the production process, the semiconductor elements and other parts can be reworked easily, as required, or, that is to say, the semiconductor elements and the like can be subsequently mounted easily.

A further object of the present invention is to provide a method of producing a semiconductor device in which the semiconductor device having superior characteristics described above can be fabricated through a simplified process within a short time, at low cost and with a high reliability and yield.

The above and other objects of the invention will be made readily understood from the detailed description below.

According to one aspect of the present invention, there is provided a semiconductor device comprising a substrate made of a resin material, semiconductor elements mounted at predetermined positions on the substrate and external connection terminals electrically connected with the semiconductor elements, in which

the semiconductor elements and the external connection terminals are embedded in the substrate and electrically connected in the substrate through wires, while the reverse surface of each of the semiconductor elements and the terminal surface of each of the external connection terminals are exposed to the same surface side of the substrate.

According to another aspect of the present invention, there is provided a method of producing a semiconductor device comprising a substrate made of a resin material, semiconductor elements mounted at predetermined positions on the substrate and external connection terminals electrically connected with the semiconductor elements, in which

the semiconductor elements and the external connection terminals are placed at predetermined positions on the obverse surface of the substrate and connected electrically to each other through wires, after which the obverse surface of the substrate is covered with the resin material of a predetermined thickness to form the substrate, while the semiconductor elements, the external connection terminals and the wires are sealed with resin in the substrate thereby to complete a semiconductor device in process, and

the completed semiconductor device in process is polished from the reverse surface of the substrate to a predetermined depth along the thickness thereof, thereby completing a semiconductor device in which the semiconductor elements and the external connection terminals are embedded in the substrate and electrically connected to each other through wires in the substrate, while the reverse surface of each of the semiconductor elements and the terminal surface of each of the external connection terminals are exposed to the same surface side of the substrate.

### BRIEF DESCRIPTION OF THE DRAWINGS

FIG. 1 is a cross-sectional view showing an example of the conventional semiconductor device having semiconductor chips mounted on the substrate thereof;

FIG. 2 is a cross-sectional view showing another example of the conventional semiconductor device having semiconductor chips mounted on the substrate thereof;

FIG. 3 is a cross-sectional view showing a semiconductor device according to a preferred embodiment of the invention;

FIG. 4 is a plan view showing the electrical connections of the semiconductor device shown in FIG. 3;

FIGS. 5A to 5D are cross-sectional views showing an example of the sequential steps for a preferred method of producing the semiconductor device shown in FIG. 3;

FIG. 6 is a cross-sectional view showing a semiconductor device according to another preferred embodiment of the invention;

FIG. 7 is a cross-sectional view showing in enlarged form the wire bonded portion of the semiconductor device shown in FIG. 6;

FIGS. 8A to 8E are cross-sectional views showing an example of the sequential steps for a preferred method of producing the semiconductor device shown in FIG. 6;

FIG. 9 is a cross-sectional view showing a semiconductor device according to another preferred embodiment of the invention;

FIGS. 10A and 10B are perspective views showing examples of the external connection terminal used for the semiconductor device according to the invention;

FIG. 11 is a perspective view for explaining the fabrication of a row of the external connection terminals used for the semiconductor device according to the invention;

FIG. 12 is a perspective view for explaining the fabrication of a row of the external connection terminals used for the semiconductor device according to the invention;

FIGS. 13A to 13D are cross-sectional views showing an example of the sequential steps for another preferred method of producing the semiconductor device according to the invention;

FIGS. 14A and 14B are cross-sectional views showing examples of the sequential steps for still another preferred method of producing the semiconductor device according to the invention; and

FIG. 15 is a cross-sectional view showing a semiconductor device according to still another preferred embodiment of the invention.

### DESCRIPTION OF THE PREFERRED EMBODIMENTS

The semiconductor device according to the present invention, like the conventional semiconductor device, has a structure comprising a substrate and semiconductor elements mounted at predetermined positions on the substrate, but unlike the conventional semiconductor device, is characterized in that the semiconductor elements and the external connection terminals used for connecting the semiconductor device and the external elements to each other are embedded in the substrate and electrically connected through wires (normally called “the bonding wires”) in the substrate, and the reverse surface (the surface opposed to the active surface) of each of the semiconductor elements and the terminal surface of each of the external connection terminals are exposed to the same surface side of the substrate.

In the semiconductor device according to this invention, the substrate having built therein the semiconductor elements, the external connection terminals, and as required, other parts including chip parts such as registers, capacitors and inductors can be formed of various materials commonly used in the field of the semiconductor device. In the practice of the invention, however, the substrate is desirably formed of a resin material from the viewpoint of the internal structure and processing need of the substrate. Further, though described in detail below, the resin material can be either conductive or insulative depending on the structure of the wires sealed.

The substrate used in this invention can be formed of a conductive resin material or an insulative resin material. In the case where the bonding wires used for connecting the semiconductor elements and the external connection terminals are conductive wires covered with an insulating film, i.e. in the case where the semiconductor device according to this invention has a coaxial structure having a insulatively covered obverse surface, the substrate can be formed of a conductive resin material. The epoxy resin or polyimide resin containing the particles or powder of a conductive metal such as copper, silver, gold, nickel or an alloy thereof in the form of a dispersed filler can be cited as an appropriate conductive resin material.

In the case where the bonding wires are formed of conductive wires alone or conductive wires covered with an insulating film and a conductive film in that order, i.e. in the case where the semiconductor device has a coaxial structure having alternate insulative and conductive coverings, the substrate is desirably formed of an insulative resin material. Epoxy resin, glass epoxy resin, polyimide resin, polyphenylether resin or polytetrafluoroether resin are included in appropriate insulative resin materials.

According to one embodiment of the invention, the substrate as described above is desirably a flexible resin substrate. The flexibility of the resin material making up such a resin substrate, as expressed by Young's modulus measured at room temperature, is 1 GPa or less. The elastomer of the silicon group, low-elasticity polyimide resin or polyolefin resin can be described as a resin material which can meet this flexibility requirement. In the case where such a flexible resin substrate is employed, the wires are movable between the semiconductor elements or the connection terminals thereof and the external connection terminals, and therefore the generation of the stress which otherwise might be caused by the difference in thermal expansion coefficient can be suppressed. Also, since the flexible substrate can be curved without causing any breakage, a compact packaging of the semiconductor device is facilitated.

With a semiconductor device according to this invention, as described above, it is desirable that the bonding wires are covered to form a coaxial structure, while at the same time similarly covering the portions connected with the wires. Specifically, it is desirable that the substrate is formed of a conductive resin material, and the wires connecting the semiconductor elements or the connection terminals thereof and the external connection terminals, the surface of the substrate which has the semiconductor elements and the external connection terminals and the terminal connectors thereof are covered with an insulating material. As an alternative, it is desirable that the substrate is formed of an insulative resin material, and the wires connecting the semiconductor elements or the connection terminals thereof and the external connection terminals, the surface of the substrate which has the semiconductor elements and the external connection terminals and the terminals connectors thereof are covered with not only an insulating material but also with a conductor (preferably, a conductive metal) thereon.

In the semiconductor device according to this invention, by employing the resin sealed structure using the conductive resin material as described above, the heat conductivity of the substrate is improved and therefore the heat radiation characteristic of the semiconductor device can be improved. Also, the conductive resin material used in the resin sealed structure improves the heat conductivity of the substrate and the heat radiation characteristic of the semiconductor device fabricated. The resin material, therefore, is desirably configured of a conductive resin of conductor dispersion type in which a conductive material having a high heat conductivity is dispersed. The conductive resin of conductor dispersion type, as described with reference to the conductive substrate above, is preferably composed of a binder resin and a filler constituting the powder or particles of a conductive metal dispersed in the binder resin. Specifically, the binder resin suitable for completion of the sealing resin is epoxy resin or polyimide resin, for example. Also, the conductive metal in the form of powder or particles to be dispersed as a filler in the binder resin is gold, silver, copper, nickel or an alloy thereof, for example. Also, whenever required, in place of such a conductive metal or in combination of such a metal, carbon black or the like may be used. As will be understood from this explanation, the word “metal” as used in this specification is defined to include, unless otherwise specified, an alloy containing any of the metals cited above as a main component.

The shape and the size of the conductive metal in powder or particle form dispersed in the binder resin as described above, though widely changeable depending on the factors such as the desired level of conductivity or the type of the metal used, is preferably a sphere normally having a diameter of about 10 to 200 μm.

With the semiconductor device according to this invention, the substrate thereof, if formed of a conductive resin material, is desirably electrically connected to the ground potential. This is because the effect of using the conductive substrate is further exhibited.

In the bonding wires having a coaxial structure, the insulating film covered on a wire (conductive wire) made of a conductor, though not specifically limited, preferably has a dielectric constant of not more than 4. The use of the coaxial wiring not only can reduce crosstalk but also can control the impedance, with few discontinuous points, by controlling the dielectric constant and the thickness of the insulating film. Further, a portion of the wire is preferably not covered with the insulating film. The presence of the portion of the bonding wire having no insulating film makes it possible to use the particular portion advantageously for connection with the ground.

In the semiconductor device according to this invention, it is essential that the reverse surface (inactive surface) of each of the semiconductor elements or the terminal surface of each of the connection terminals thereof and the terminal surface of each of the external connection terminals be exposed to one of the main surfaces of the device. By employing this configuration, the semiconductor device can be configured in simple fashion with a higher reliability. Not only that, a semiconductor device packaged three-dimensionally at high density can be provided without using an expensive substrate or a complicated production process.

The layout, distribution and the size of the semiconductor elements or the connection terminals thereof and the external connection terminals to be formed on the substrate are not specifically limited but can be similar to those of the conventional semiconductor device. Specifically, the connection terminals of the semiconductor elements can be arranged in an area array in accordance with the configuration of the semiconductor elements, and the external connection terminals can be arranged in an area array pattern correspondingly.

As one preferable example, in the semiconductor device according to this invention, the connection terminals of the semiconductor elements are arranged in a plurality of areas on one surface of the substrate, and each semiconductor element is arranged substantially at the central portion of each of such areas. The connection terminals of the semiconductor elements in adjacent areas are connected electrically to each other through wires inside the substrate according to this invention. This electrical connection may be between the connection terminals of the semiconductor elements or between the connection terminals of the semiconductor elements and the external connection terminals. The use of this configuration makes it possible to mount a plurality of semiconductor elements in one semiconductor device, and therefore the configuration can be advantageously utilized for fabrication of a multi-chip module or the like.

The connection terminals of the semiconductor elements and the external connection terminals can have a similar configuration to the terminals used for the conventional semiconductor device. Specifically, these terminals can be arranged, for example, on the obverse surface of the substrate in the form of exposed pads or the like. These terminals may be configured in the form of a single layer, or may alternatively be configured in the form of two or more multiple layers, as required. Also, these terminals may be formed of any material to the extent that the desired electrical connection is possible. The proper terminal material is a conductive material of a metal or the like. The proper conductive metal is gold, silver, copper, palladium, cobalt, nickel or an alloy thereof. Further, these connection terminals, as required, may have on the surface thereof such means as bumps or lands for improving the reliability of connection as in general practice in the field of the wiring board.

The connection terminals of the semiconductor elements and the external connection terminals described above may each be formed according to the conventional technique. The proper method of forming terminals include a method of forming the terminals by selectively plating a predetermined area on the substrate or a method of plating the entire surface of the substrate in the presence of a resist mask and then exposing only the terminals by removing the mask. In the semiconductor device according to the invention, these connection terminals, in particular, are advantageously formed of a conductive metal pole.

The connection terminals formed of a metal pole can assume various shapes and can be formed using various techniques. According to this invention, conductive wires or conductive poles (such as solid circular cylinders or prisms) are sealed with resin for forming the substrate, after which the hardened sealing resin is ground and polished from one side, thereby advantageously forming a substrate of a predetermined thickness having internal connection terminals extending along the thickness thereof. Generally speaking, these connection terminals, if circular, have a diameter of about 100 to 200 μm.

With the semiconductor device according to this invention, as explained briefly above, the bonding wires generally used in the field of the semiconductor device can be used to connect the semiconductor elements or the connection terminals thereof with the external connection terminals. The bonding wires used in this invention, which are required to be contained within the substrate, however, are required to be hermetically sealed in the substrate and therefore are required to have a sufficient strength to be resistant to such a situation.

The bonding wires preferably have a coaxial structure especially to avoid the generation of crosstalk. Specifically, the bonding wire is advantageously constituted of a conductor wire of a conductive material (conductor), an insulating film covering the conductive wire and, if required, a conductive film further covering the insulating film. The conductive material making up the core member of the wire is preferably a conductor such as a metal. The proper conductive metal is, for example, gold, silver, copper, nickel, aluminum or an alloy thereof. Also, the insulating film covering this conductive wire is preferably an insulative resin coating such as of epoxy resin or polyimide resin. In the case of an aluminum wire, on the other hand, an oxide film is also effective. The resin coating can be formed by, for example, electrostatic coating, spray coating or dip coating. The conductive film covered further on the insulating film as required, like the core member of the wire, can preferably be formed by vapor deposition or plating from a conductive metal such as gold, silver, copper, nickel, aluminum or any alloy thereof.

The bonding wire may have various sizes depending on the position of use thereof in the substrate or the timing at which the insulating film or the conductive film is covered. The diameter of the core member is normally about 20 to 40 μm. The thickness of the insulating film covered on the core member is normally about 2 to 8 μm in the case where the wire bonding is carried out using a conductor wire covered with an insulating film in advance. The thickness of the insulating film is normally about 10 to 50 μm, however, in the case where the insulating film is covered around the conductor wire after carrying out the wire bonding using the conductor wire not covered with the insulating film. The thickness of the insulating film may be varied with the requirement of impedance matching and the material used for the insulating film. In the semiconductor device according to this invention, the wiring board may be given a capacitance by adjusting the material (dielectric constant) and the thickness of the insulating film taking the conductive resin surrounding the wire into consideration. The conductive film also may normally have about the same thickness as the insulating film.

The semiconductor device according to the invention can be used alone. Preferably, however, a plurality of the semiconductor devices are used as a stack or laminated product by being electrically connected to each other through the corresponding external connection terminals, respectively. The manner in which the semiconductor devices are stacked may be arbitrarily changed.

The semiconductor elements to be mounted on the semiconductor device according to the invention are not specifically limited. Therefore, any of various semiconductor chips such as an IC chip, a LSI chip, a C/C, etc. can be included. Also, the semiconductor chip can be mounted using a common method such as the flip chip mount or the chip mount. The semiconductor elements, after being mounted on the wiring board, are sealed with an appropriate insulative resin. Further, with the semiconductor device according to the invention, other chip parts such as a resister, a capacitor or an inductor may be mounted in place of or in combination with the semiconductor elements.

The semiconductor device according to the invention, is capable of being produced in accordance with any of various processes. Generally, the semiconductor device can be advantageously produced by the steps of:

(1) placing semiconductor elements (including the connection terminals of the semiconductor elements, as required) at predetermined positions on the substrate surface;

(2) electrically connecting the semiconductor elements and the external connection terminals to each other through wires (bonding wires);

(3) making a substrate by covering the substrate surface with a resin material of a predetermined thickness, while at the same time sealing the semiconductor elements and the external connection terminals with resin in the substrate thereby to complete a semiconductor device in process; and

(4) grinding and polishing the completed semiconductor device in process to a predetermined depth along the thickness thereof from the reverse (inactive) surface of the substrate.

According to this production process, the semiconductor elements and the external connection terminals are embedded in the substrate and electrically connected to each other through wires inside the substrate, thereby completing a semiconductor device with the reverse surface of the semiconductor elements and the terminal surface of the external connection terminals exposed to the same surface side.

Several preferable processes for producing the semiconductor device according to this invention will be explained hereinafter. In the description that follows, the details of each elements making up the semiconductor device have already been described and therefore will not be explained again.

The method of producing a semiconductor device according to this invention starts with preparing a substrate used as a support member of semiconductor elements up to the intermediate stage of the fabrication process. The substrate is removed by grinding in a subsequent stage and, therefore, is preferably made of an inexpensive material easy to grind but not extensible. An example of the proper substrate material is glass, epoxy resin, acryl resin, glass epoxy resin, ceramic, a 42 alloy (Fe with 42 % Ni) or the like metal.

Then, semiconductor elements (semiconductor chips), and when required, connection terminals for connecting the semiconductor elements and external connection terminals are mounted at predetermined positions on one surface of the substrate thus prepared. In some cases, other elements and parts required for completing the semiconductor device may be mounted in this stage. The semiconductor elements, the external connection terminals, etc. can be mounted by a method generally used in the field of the semiconductor device. For example, the external connection terminals can normally be mounted advantageously by the resist process. Specifically, the resist is covered over the entire surface of the substrate prepared and then removed from the places where the external connection terminals are to be formed. In the next step, the material such as gold, palladium, cobalt or nickel for forming the external connection terminals is electrolytically plated to a predetermined thickness in such a manner as to cover the resist and the underlying substrate (exposed portion). Once the resist is removed, the plating layer, i.e. the external connection terminals alone, is left on the substrate.

The electrolytic plating will be explained further. This process can be carried out according to various methods commonly used for fabrication of the semiconductor device. Also, in the case where the electrolytic plating is used to form the respective connection terminals, the terminals are normally formed as a single layer. Nevertheless, they may alternatively be formed as a composite pad having a multilayer structure, as required. Specifically, a first pad is formed by plating a metal of low melting point, followed by forming a second pad by plating a metal having a higher melting point than the metal of a low melting point. The metal of a low melting point is preferably an alloy. The proper alloy of a low melting point is, for example, tin-lead (SnPb) alloy, tin-silver (SnAg) alloy, tin-copper-silver (SnCuAg) alloy or the like. Further, in the case where the terminal of composite pad type is formed in the aforementioned manner, the first pad is formed preferably under such conditions that the resulting pad area is larger than the area of the second pad.

Further, in the production of the semiconductor device according to this invention, the external connection terminals made of conductive metal poles are preferably placed on the substrate. Specifically, rods (say, metal poles) of a conductive metal formed through the substrate are arranged at predetermined positions on the substrate so that the connection terminals of the semiconductor elements and the external connection terminals may be formed on the end surface of each metal pole exposed to one surface of the substrate. The metal pole as referred here is a wire, a solid circular cylinder or a prism of a metal. As the next step, the semiconductor elements or the connection terminals thereof and the external connection terminals are connected electrically to each other through wires as described below, after which one of the surfaces of the substrate is covered with a resin material of a predetermined thickness. Then, a substrate is formed with the semiconductor elements, the external connection terminals and wires sealed with resin therein.

In the production process described above, the metal poles can be formed by various methods. For example, a proper substrate material is prepared and the portions where the metal poles are to be formed are etched off selectively. After that, the metal poles are embedded, or preferably, a metal material suitable for forming the metal poles is filled or plated. More specifically, the metal poles can be formed by any one of the methods described in Japanese Unexamined Patent Publication (Kokai) Nos. 8-78581, 9-331133, 9-331134 and 10-41435, for example.

Next, the semiconductor elements or the connection terminals thereof and the external connection terminals are electrically connected to each other through wires. This electrical connection can be established advantageously using, instead of the conventional conductor wires, the bonding wires made of conductor wires covered with an insulating film and, as required, further with a conductor film, as described above.

In the production of the semiconductor device of this invention, especially after electrically connecting the semiconductor elements and the external connection terminals through conductor wires, an insulative resin material is covered on the surfaces of the wires connecting the semiconductor elements and the external connection terminals, the surfaces of the semiconductor elements and the external connection terminals, and other exposed portions on the substrate. Then, preferably, the insulative film is further covered with a conductive metal material.

Further, in the production of the semiconductor device of the invention, after connecting the semiconductor elements and the external connection terminals electrically through bonding wires, the performance of each of the connected members is preferably tested according to a predetermined procedure. In the case where a defect is found as the result of this test, the mounted semiconductor elements, the external connection terminals, etc. can be reworked. The rework can be carried out by removing the semiconductor elements found defective, by spot heating, and replacing it with a brand new semiconductor element. This rework can be carried out during the production process, i.e. with the semiconductor elements and the chip parts exposed, and therefore the product yield can be improved without sacrificing the other semiconductor elements, etc. The electrical tests that can be used in this case include the connection/conduction test and the basic operation test at room temperature.

Upon completion of the wire bonding work and, as required, the electrical test described above, the substrate surface is covered with the substrate-forming resin material to a predetermined thickness thereby to complete a semiconductor device in process with the semiconductor elements, the connection terminals thereof, the external connection terminals and the wires sealed therein with resin. This resin sealing process can be carried out normally by covering a selected resin material by transfer molding or potting.

After completion of the resin sealing process, the unrequired portions of the resulting semiconductor device in process are removed by grinding and polishing. This process can be carried out advantageously by grinding the semiconductor device in process to a predetermined depth from the reverse surface (substrate) thereof using an appropriate grinding tool and polishing means. For example, a back grinder for a silicon wafer is suitably used. If required, the upper surface of the semiconductor device in process can also be ground and polished by using a similar method. In this way, a thin semiconductor device according to this invention having the configuration described above can be obtained.

The method of producing the semiconductor device described above can be embodied in various modifications.

For example, as described above, a semiconductor and the like are mounted on one surface of the substrate and connected by bonding wires, and the surface of the substrate is covered with a resin material to a predetermined thickness. After forming a semiconductor device in process with the semiconductor elements and the like sealed therein in this way, apertures each smaller than the diameter of the semiconductor element connection terminals and the external connection terminals is formed through the substrate at predetermined positions on the substrate supporting the semiconductor device in process, i.e. at positions in contact with the semiconductor element connection terminals and the external connection terminals. These apertures can be formed advantageously, normally, by masking the portions other than the apertures and etching off the substrate material in the etching process. According to another method, after forming the apertures at predetermined positions on the substrate, a series of processes for forming the connection terminals, the wire bonding and sealing with resin may be carried out.

After forming the apertures in the substrate in the aforementioned way, the apertures are filled with a metal of low melting point. Specifically, the substrate is heated to a temperature slightly higher than the melting point of the low-melting-point metal and, after shrinking, the low-melting-point metal, the substrate and the masking means (normally, resist) remaining on the surface thereof are removed by an appropriate etching solution. Then, the low-melting-point metal remaining unmolten on the semiconductor connection terminals and the external connection terminals is reflowed again into a sphere. Thus, bumps can be obtained which can be used as semiconductor connection terminals and external connection terminals.

### EXAMPLES

Examples of the present invention will be explained below with reference to the accompanying drawings. By the way, it should be understood that the present invention is not limited to the examples described below.

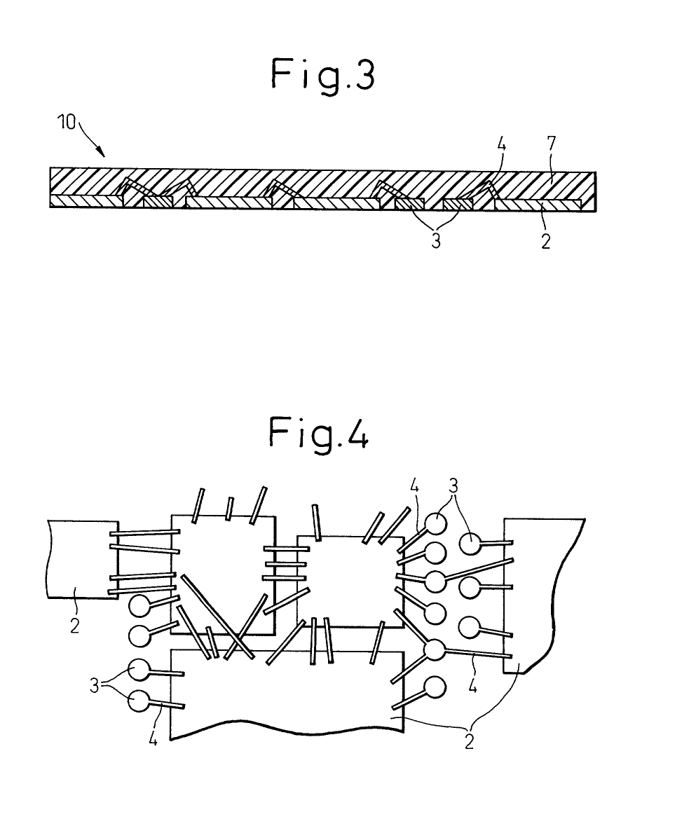

FIG. 3 is a cross-sectional view showing a semiconductor device according to a preferred embodiment of the invention, and FIG. 4 is a plan view showing the electrical connections of the semiconductor device of FIG. 3. A semiconductor device 10, as shown, comprises a substrate 7, semiconductor elements (semiconductor chips) 2 built in the substrate 7 and external connection terminals 3. In the semiconductor device 10 according to this invention, the reverse surface, i.e. the inactive surface of each semiconductor device 2 and the terminal surface of each external connection terminal 3 are exposed to the same surface side at the same height, that is to say, without any unevenness. The semiconductor elements 2 and the external connection terminals 3 are connected electrically to each other by bonding wires 4. Though not shown, the semiconductor device 10 may have in or on the surface thereof, chip parts, wirings, substrate components and the like, as required and as conventionally used in the prior art.

In the illustrated semiconductor device 10, the substrate 7 is configured of a conductive resin material. The bonding wires 4 embedded in the substrate 7 have a coaxial structure including a conductive wire (core member) and an insulative film (covering, not shown for simplification) covering the conductive wire in order to insulate itself from the substrate 7. The conductive wire is formed of a conductive metal (gold in this case) and has the surface thereof covered with an insulating film of an insulative coating. In the case where the substrate 7 is configured of an insulative resin material, the insulative covering of the bonding wires 4 is not required.

The illustrated semiconductor device 10 may be modified variously. For example, though not shown, the external connection terminals may be each coupled with a solder ball which is further connected with external parts. Also, the insulative film covering the conductive wire may be further extended over the surface of the semiconductor elements and the external connection terminals as well as on the surface of the wires.

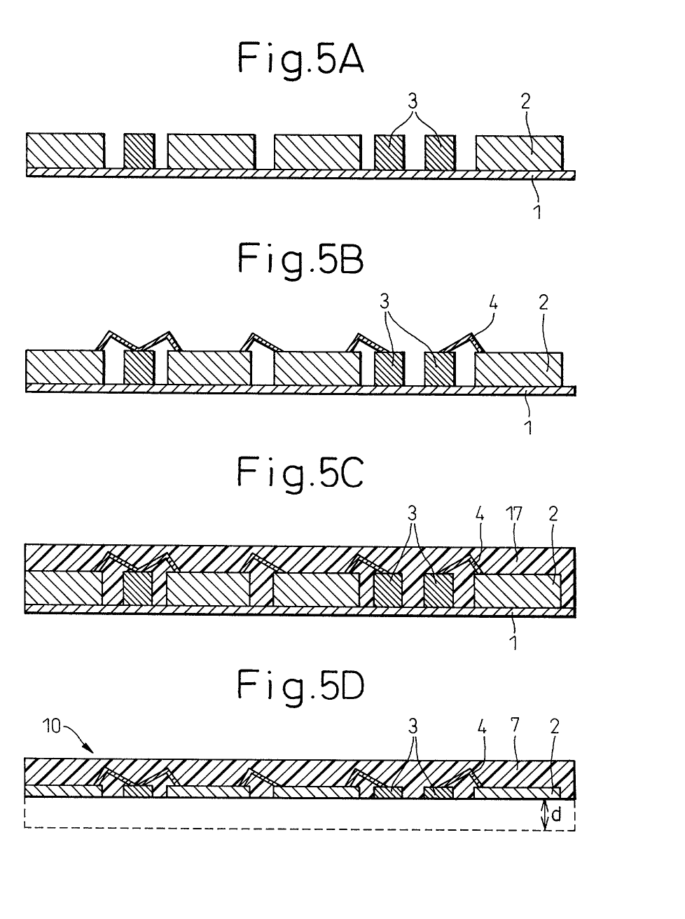

The semiconductor device 10 shown in FIGS. 3 and 4 may be produced in accordance with the steps shown in sequence in FIGS. 5A to 5D, for example.

First, as shown in FIG. 5A, the semiconductor chips 2 and the external connection terminals 3 are placed in a predetermined pattern on one surface of the substrate 1 composed of a thin material (glass epoxy resin this case) which is easy to grind. The semiconductor chips 2 are placed with the active surface thereof up. The external connection terminals 3 are formed of a solid circular cylinder of copper having a predetermined section and continuous along the thickness thereof.

Then, as shown in FIG. 5B, the connection terminals (not shown) of the semiconductor chips 2 of the substrate 1 and the external connection terminals 3 are electrically connected to each other by the bonding wires 4. The bonding wires 4 used in this case are coaxial wires as described above. For forming the coaxial wires, a core member of gold (gold wire), for example, is wire-bonded to each terminal in the first step. Upon complete bonding of the terminals to each other, the electrical test of the semiconductor chips 2 is conducted. In the event that a defect of any semiconductor chip is detected by this test, the particular semiconductor chip is replaced with a new semiconductor chip. Though not shown, chip parts, if any are mounted, can be reworked in similar fashion.

Then, with the substrate 1 connected to the ground, a powder of an insulative resin (epoxy resin) is electrostatically coated. Instead of covering an insulating film by electrostatic coating, the method of resin dipping or vapor deposition may be employed. In this way, the bonding wires 4 covered with an insulating film (not shown) of uniform thickness are obtained. By the way, the insulating film is covered also on the surface of the semiconductor chips 2 and the external connection terminals 3.

Next, as shown in FIG. 5C, the surface of the substrate 1 holding the elements, etc. is wholly sealed with resin. In the case under consideration, an epoxy resin solution containing a conductive filler (copper powder) in dispersed form is used. The surface of the substrate 1 is covered with the resin material 17 having a predetermined thickness, so that the semiconductor chips 2, the external connection terminals 3 and the bonding wires 4 are sealed with resin inside the substrate 1. In the present invention, the device in this sealed state is called “the semiconductor device in process”.

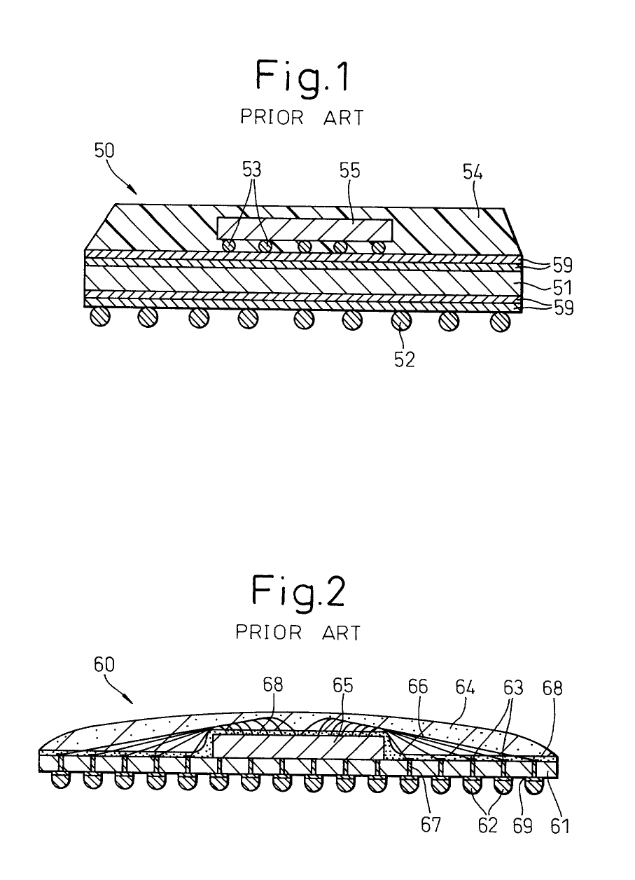

After completion of the aforementioned resin sealing process, the process for thinning the semiconductor device is entered. Specifically, as shown in FIG. 5D, the semiconductor device in process prepared in the previous step is ground from the reverse surface thereof to the depth d, i.e. to the depth not reaching the active area of the semiconductor chips 2, and the ground surface is flattened by being polished. A normal back grinder for silicon wafers, for example, may be used for the grinding. For the polishing process, on the other hand, colloidal silica or the like can be used. In this way, the semiconductor device 10 explained above with reference to FIG. 1 is produced.

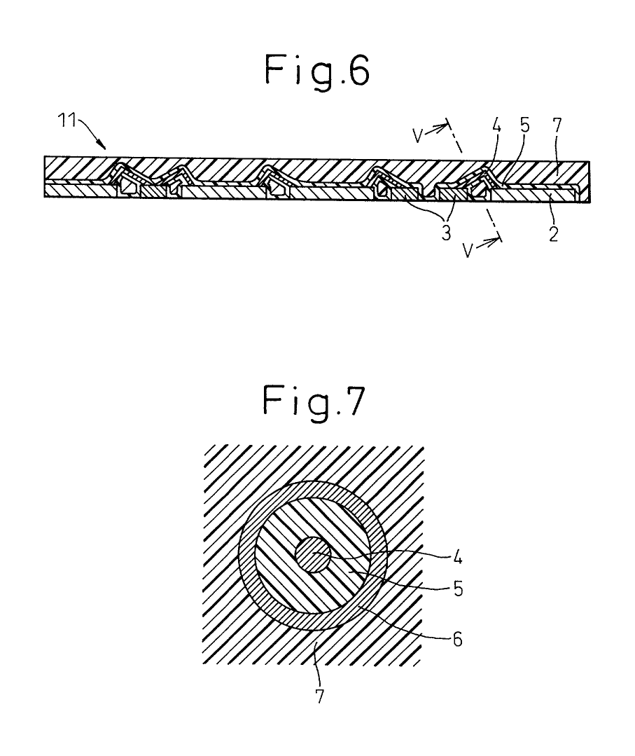

FIG. 6 is a cross-sectional view showing a semiconductor device according to another preferred embodiment of the invention. The illustrated semiconductor device 11 has a configuration similar to the semiconductor device 10 explained above with reference to FIG. 3. As will be understood from the sectional view (sectional view taken in line V-V in FIG. 6) illustrating in enlarged form the wire bonded portion of the semiconductor device 11 shown in FIG. 7, the surfaces other than the reverse surface of the semiconductor chips 2 and the terminal surfaces of the external connection terminals 3 (both are exposed), i.e. the surfaces including the obverse surface of the semiconductor chips 2, the obverse surface of the external connection terminals 3 and the obverse surface of the bonding wires 4 are covered with a conductive film or preferably with a conductive metal film 6 through a layer of an insulating film 5. Thus, the substrate 7 is formed of an insulative resin material (sealing resin). The substrate 7 of the shown semiconductor device 11 may of course be configured of a conductive resin material as an alternative.

With reference to FIG. 7, an explanation will be given more specifically. In this semiconductor device 11, the substrate 7 is formed of an insulative polyimide resin, while each bonding wire 4 is configured of the conductive wire 4 of a conductive metal, the insulating film 5 covering the conductive wire 4 and the conductive metal film 6. Though not shown, if required, a part of the insulating film 5 may be removed from the bonding wire 4. By doing so, the conductive wire 4 can be used directly as the ground.

In the semiconductor device 11 shown in FIG. 6, the dielectric constant and the thickness of the insulating film 5 for the bonding wires 4 embedded in the semiconductor device 11 are preferably controlled appropriately. By doing so, the impedance can be controlled without any discontinuous points. For example, the conductive wires 4 can be formed of a common conductive metal, while the insulating films covering them can be formed of different materials having different dielectric constants.

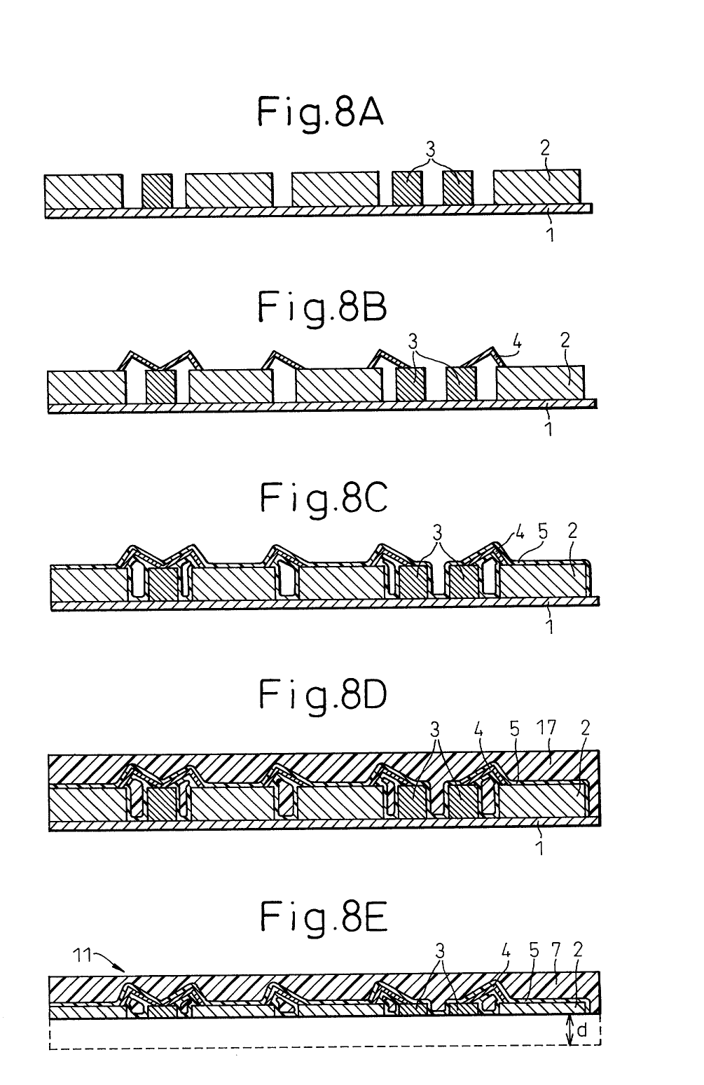

The semiconductor device 11 shown in FIG. 6 can be produced, for example, by following the steps shown in sequence in FIGS. 8A to 8E. This method is similar to that shown in FIGS. 5A to 5D.

First, as shown in FIG. 8A, the semiconductor chips 2 and the external connection terminals 3 are placed in a predetermined pattern on one surface of a substrate 1 composed of a thin material (glass epoxy resin also in this case) easy to grind. The semiconductor chips 2 are placed with the active surface thereof up. The external connection terminals 3 are formed of a solid circular cylinder of copper having a predetermined section and continuous along the thickness thereof.

Then, as shown in FIG. 8B, the connection terminals (not shown) of the semiconductor chips 2 of the substrate and the external connection terminals 3 are electrically connected to each other by the bonding wires 4. The bonding wires 4 are gold wires each having a diameter of 25 μm.

After completion of the electrical connection by the bonding wires 4, an electrical test is conducted to check whether the proper connection is established or not. In the case where a defect or connection failure of any of the semiconductor chips is confirmed in this test, the particular semiconductor chip is replaced with a new semiconductor chip or is partially reconnected.

Thereafter, as shown in FIG. 8C, with the substrate 1 connected to the ground, the insulative epoxy resin powder is electrostatically coated to cover the insulating film 5 made of epoxy resin. As shown, the obverse surface of the semiconductor chips 2, the obverse surface of the external connection terminals 3 and the obverse surface of the bonding wires 4 are thus covered with a layer of the insulating film 5. Specifically, the insulating film 5 surrounds the wire 4 thereby to make up a coaxial structure as shown in FIG. 7. The thickness of the insulating film 5 is about 10 μm.

Then, though not shown, the insulating film 5 of the bonding wire 4 having the coaxial structure is further covered with a conductive metal thereby to form a conductive metal film described above with reference to FIG. 7. In the case under consideration, the conductive metal film is formed by the electroless plating of copper. The thickness of the conductive metal film is about 0.6 μm.

In the next step, as shown in FIG. 8D, the surface of the substrate holding the elements or the like is wholly sealed with resin by potting in the solution of the insulative polyimide resin. As shown, the obverse surface of the substrate 1 is covered with a resin material 17 having a predetermined thickness, so that the semiconductor chips 2, the external connection terminals 3 and the bonding wires 4 are sealed with resin in the substrate 1.

After completion of resin sealing as described above, as shown in FIG. 8E, the process for reducing the thickness of the semiconductor device is begun. Specifically, the semiconductor device in process prepared in the previous step is ground from the reverse surface thereof to the depth d, and then the ground surface is flattened by being polished. Thus, the semiconductor device 11 is obtained as explained above with reference to FIG. 6.

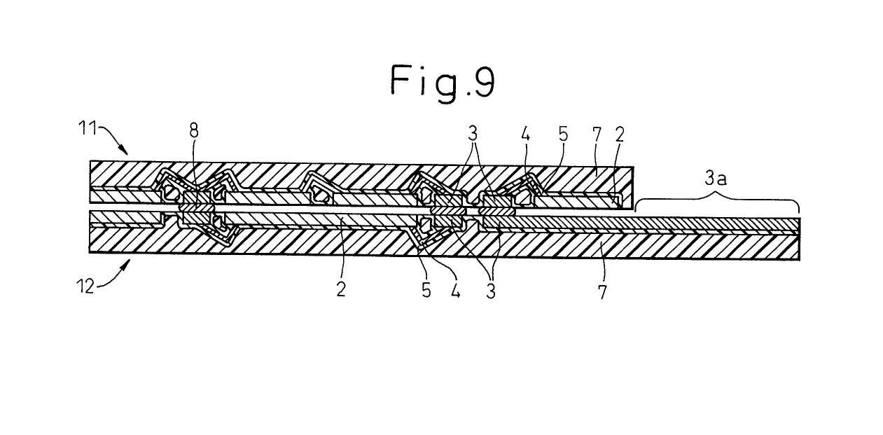

FIG. 9 illustrates an example of the configuration in which the semiconductor device 11 shown in FIG. 6 and another semiconductor device 12 according to the invention are stacked to make up a memory card. The semiconductor device 12, as shown, comprises a substrate 7, semiconductor elements 2 embedded in the substrate 7 and external connection terminals 3. The semiconductor elements 2 and the external connection terminals 3 are electrically connected to each other by bonding wires 4 having a coaxial structure. The semiconductor devices 11 and 12 are connected to each other by connecting the external connection terminals 3 of the semiconductor devices to each other through solder bumps 8. Also, in the case where this stacked semiconductor device is used as a memory card, the external connection terminal 3a exposed to the end portion of the semiconductor device 12 can be used as an external connector for a card insertion slit. The external connection terminal 3a is in the shape of a lead (an elongate tabular member).

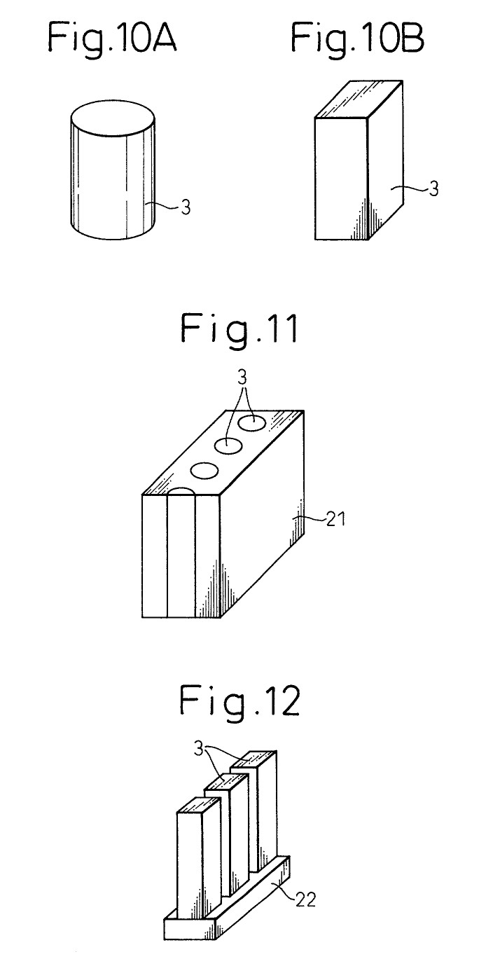

FIGS. 10A and 10B show examples of a conductive metal cylinder usable advantageously as an external connection terminal of the semiconductor device according to this invention. FIG. 10A shows a circular solid copper cylinder 3, and FIG. 10B shows a copper prism 3. These metal cylinders can be acquired at low cost and easily on the one hand and has a constant sectional shape continuous along the thickness on the other hand. Also, a plurality of these metal cylinders can be located with small pitches without any trouble, and therefore find a suitable application as external connection terminals.

The external connection terminals of metal cylinders can be formed according to various methods. Especially, the methods described in the Japanese unexamined patent publication (Kokai) gazettes cited above can be advantageously carried out. An example is shown in FIG. 11 in which a multiplicity of circular solid cylinders 3 are embedded in the resin or ceramic 21 with small pitches. These circular solid cylinders 3 are placed on the substrate and sealed with resin thereby to make up the external connection terminals according to the invention. FIG. 12 shows an example utilizing the prisms 3. The prisms 3 are placed on an appropriate substrate 22 to make up external connection terminals. Specifically, a substrate 22 is coupled to one surface of the substrate 1 (see above) and by grinding and polishing, the substrates 1 and 22 are removed in that order, so that individual external connection terminals made of the prisms 3 can be formed. By the way, the solid circular cylinders and the prisms can be formed easily by stamping a metal plate.

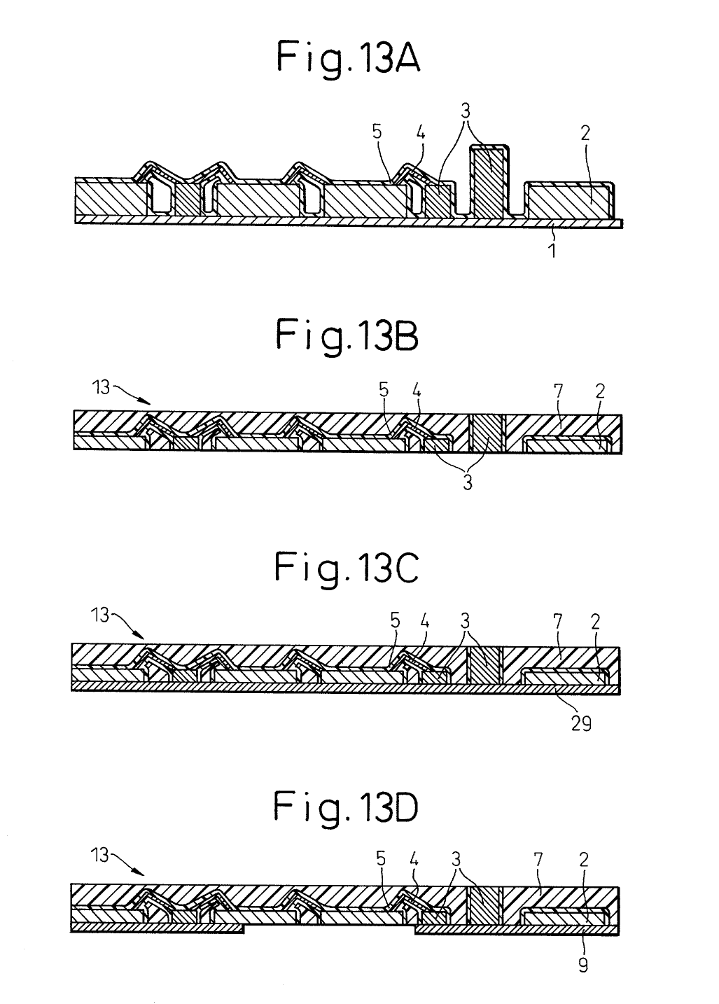

FIGS. 13A to 13D show, in sequence, the production steps of still another preferred method of producing a semiconductor device according to the invention. In this semiconductor device, a structure is employed in which a part of the external connection terminals are arranged along the entire thickness of the device to make up external connection terminals of through type to which the semiconductor chips are not connected. As will be understood from the description below, this semiconductor device can be fabricated basically by a similar method to the one explained above with reference to FIGS. 5A to 5D and FIGS. 8A to 8E.

First, as shown in FIG. 13A, the semiconductor chips 2 and the external connection terminals of solid circular copper cylinders are placed on one surface of the substrate 1 made of glass epoxy resin. Those of the external connection terminals higher than the others are used to form the external connection terminals of a through type.

Then, the semiconductor chips 2 and the corresponding external connection terminals 3 are electrically connected to each other by bonding wires (gold wires) 4, and an electrical test is conducted to check whether the electrical connection is correctly established by the bonding wires 4.

Upon completion of the electrical test, with the substrate 1 connected to the ground, the insulative epoxy resin powder is electrostatically coated. The obverse surface of the semiconductor chips 2, the obverse surface of the external connection terminals 3 and the obverse surface of the bonding wires 4 are covered with an insulating film 5 of epoxy resin. Then, though not shown, a conductor film is formed further by coating gold on the insulating film 5 of the bonding wires 4 having a coaxial structure by electroless plating.

Then, though not shown, the whole surface of the substrate 1 holding the elements is sealed with resin by potting in a solution of the insulative polyimide resin. The obverse surface of the substrate thus is covered with a resin material of predetermined thickness, so that a semiconductor device in process is produced within which the semiconductor chips, the external connection terminals and the bonding wires are sealed with resin.

Then, in order to reduce the thickness of the semiconductor device, as shown in FIG. 13B, the semiconductor device in process prepared in the previous step is ground to a predetermined depth from both the obverse and reverse surfaces thereof, and the surfaces thus ground are flattened by being polished. Thus, the illustrated semiconductor device 13 is obtained.

After completing the semiconductor device 13 as described above, the connection wires are formed further on the lower surface of the semiconductor device. First, as shown in FIG. 13C, a copper foil 29 is attached on the whole lower surface of the semiconductor device 13. In the next step, as shown in FIG. 13D, the copper foil 29 is patterned by the conventional photolithography in accordance with the desired wiring pattern. In this way, the semiconductor device 13 having the connection wires 9 on the lower surface thereof is produced as shown. By the way, the connection wires 9 may be formed by the additive method or the semi-additive method using the electroless copper plating or the electrolytic copper plating.

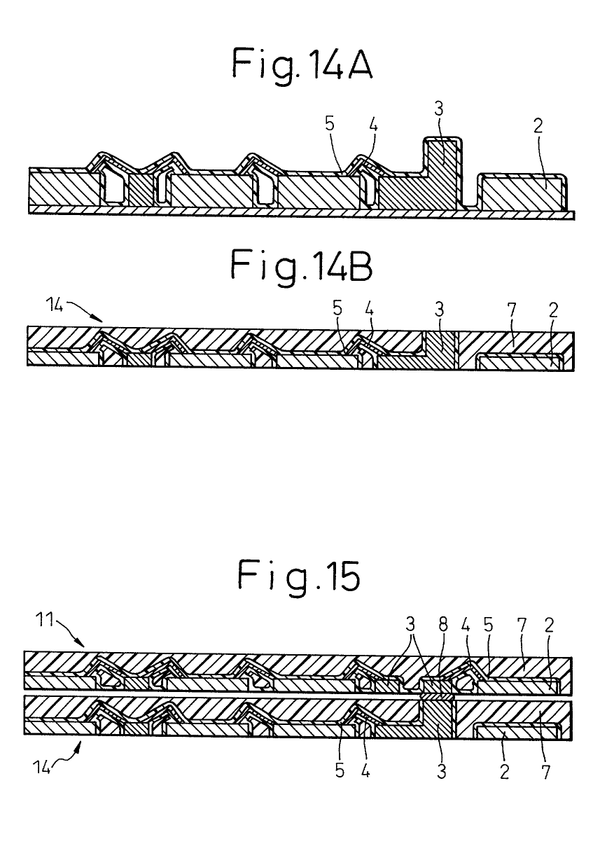

FIGS. 14A and 14B are cross-sectional views showing the sequential steps of still another preferred method of producing a semiconductor device according to this invention. This semiconductor device is similar to the semiconductor device 11 shown in FIGS. 13A to 13D with the exception that the shape of a part of the external connection terminals is changed. Basically, therefore, it can be produced by a similar method to the one described above with reference to FIGS. 13A to 13D.

First, as shown in FIG. 14A, the following series of jobs are carried out.

(1) Semiconductor chips 2 and external connection terminals 3 of circular copper solid cylinders are placed on one surface of a substrate 1 of glass epoxy resin. The external connection terminals 3 formed in this case are of two types. The external connection terminals 3 of smaller height constitute connectors for connecting the bonding wires 4, while the external connection terminals 3 of larger height constitute those of through type formed through the substrate 7.

(2) The semiconductor chips 2 and the external connection terminals 3 are electrically connected to each other by the bonding wires (gold wires) 4.

(3) An electrical test is conducted to check whether the correct electrical connection is established by the bonding wires 4.

(4) With the substrate 1 connected to the ground, the insulative epoxy resin powder is electrostatically coated thereby to form an insulating film 5.

(5) Gold is further coated, by electroless plating, on the insulating film 5 of the bonding wires 4 having a coaxial structure thereby to form a conductor film (not shown).

Then, though not shown, the product in process prepared in step of FIG. 14A is potted with a solution of insulative polyimide resin, so that the surface of the substrate holding the elements, etc. is wholly sealed with resin. The substrate surface is thus covered with a resin material having a predetermined thickness, thereby producing a semiconductor device in process within which the semiconductor chips, the external connection terminals and the bonding wires are sealed with resin.

Then, in order to reduce the thickness of the semiconductor device, as shown in FIG. 14B, the semiconductor device in process prepared in the previous steps is ground to a predetermined depth from both the obverse and reverse surfaces thereof, and the surfaces thus ground are flattened by being polished. The illustrated semiconductor device 14 thus can be produced.

FIG. 15 shows an example of a semiconductor device having a multilayer connection structure produced by stacking the semiconductor device 11 shown in FIG. 6 and another semiconductor device 14 (produced as described above) according to this invention one on the other. These two semiconductor devices 11 and 14 are connected to each other by connecting the external connection terminals 4 of the respective semiconductor devices to each other using the respective solder bumps 8. In this semiconductor device stack, still another semiconductor device can be connected to the lower side of the semiconductor device 14 through the external connection terminals 3 thereof. In forming this semiconductor device stack, the semiconductor device 13, for example, of which the fabrication method is described above with reference to FIGS. 13A to 13D may also be combined.

As can be appreciated from the above, according to this invention, the various functions and effects described below can be obtained.

(1) A semiconductor device packaged three-dimensionally, and highly densely, can be produced easily without using any expensive material or any sophisticated technique.

(2) The mounting height of the semiconductor elements can be reduced and unified at the same time, thereby making it possible to produce a thin semiconductor device.

(3) The conventional semiconductor device employing the built-up structure poses the problem of connection reliability as the semiconductor elements, etc. are electrically connected using a multiplicity of connectors (via connectors, for example). According to this invention, in contrast, the component parts in the substrate can be connected with a single bonding wire on the one hand and detailed connections are not required on the other hand. Therefore, the reliability of the connections in the substrate is remarkably improved. Also, the reliability is not adversely affected even in the case where the space between the connection terminals is small.

(4) The surface of the conductor wires is covered with an insulative resin and the substrate is formed of a conductive resin (the substrate is assumed to be at the ground potential). In this way, the bonding wires of a coaxial structure can be obtained, thereby making it possible to suppress or prevent the generation of crosstalk between wires.

(5) In the case where the substrate with the semiconductor elements, the external connection terminals and the bonding wires embedded therein is configured of a conductive resin of dispersed conductor type in which the particles of a conductive material are dispersed, in particular, the heat conductivity of the substrate itself is improved and therefore the radiation characteristic of the semiconductor device is also improved.

(6) In the case where the surface of the conductive wires is covered with an insulative resin, the internal impedance of the substrate can be easily matched by changing the thickness of the resulting insulating film or the dielectric constant of the insulative resin used for the insulating film. Further, in the case where a covering (outer film) of a conductive metal material is used in combination with the insulative resin covering described above, the impedance can be controlled with fewer discontinuous points by controlling the dielectric constant and thickness of the covering.

(7) Since the structure is simple, the semiconductor device can be fabricated at low cost within a short time through a simplified process. Also, the simple structure makes it possible to take versatile action against any design change of the device. In other words, the semiconductor device according to this invention has a high design latitude.

(8) The semiconductor device can be provided without wiring patterns built in, i.e. with the semiconductor elements and the external connection terminals exposed. Therefore, the multiple requirements of the semiconductor device manufactures can be met.

(9) An electrical connection test of the semiconductor elements can be conducted during the production of the semiconductor device, i.e. after completion of the wire bonding, and therefore the elements can be reworked as required before completion of the device. Also, in view of the fact that defective semiconductor elements to be replaced are exposed, the other semiconductor elements, free of defects, are not sacrificed.

1. A semiconductor device comprising a substrate made of a resin material, semiconductor elements mounted at predetermined positions on said substrate and external connection terminals electrically connected with said semiconductor elements, in which
said semiconductor elements and said external connection terminals are embedded in said substrate and connected electrically in said substrate through wires, and the back of each of said semiconductor elements and the terminal surface of each of said external connection terminals are exposed to the same surface side of said substrate.

2. A semiconductor device according to claim 1, in which said substrate is made of a conductive resin material, and each of said wires is a conductive wire covered with an insulating film.

3. A semiconductor device according to claim 2, in which said conductive resin material is formed of a binder resin and a conductive material dispersed in said binder resin.

4. A semiconductor device according to claim 1, in which said substrate is made of an insulative resin material, and each of said wires is a conductive wire covered with an insulating film and a conductive film in that order.

5. A semiconductor device, as described in claim 1, in which said substrate is made of an insulative resin material, and the wires for connecting said semiconductor elements and said external connection terminals, the obverse surface of each of said semiconductor elements and the obverse surface of each of said external connection terminals are covered with an insulative resin layer and a conductive metal layer in that order.

6. A semiconductor device according to any one of claims 1 to 5, in which a plurality of said semiconductor devices are electrically connected to each other through external connection terminals, respectively, and stacked in the thickness of said substrate.

7. A method of producing a semiconductor device comprising a substrate made of a resin material, semiconductor elements mounted at predetermined positions on said substrate and external connection terminals electrically connected with said semiconductor elements, in which
the semiconductor elements and the external connection terminals are placed at predetermined positions on the obverse surface of the substrate, and said semiconductor elements and said external connection terminals are electrically connected to each other through wires, after which the obverse surface of said substrate is covered by a resin material to a predetermined thickness thereby to constitute a substrate, while at the same time sealing said semiconductor elements, said external connection terminals and said wires with resin in said substrate thereby to constitute a semiconductor device in process, and
in which said semiconductor device in process is polished to a predetermined depth along the thickness from the reverse surface side of said substrate, said semiconductor elements and said external connection terminals are embedded in said substrate and electrically connected to each other in said substrate through wires, and the reverse surface of each of said semiconductor elements and the terminal surface of each of said external connection terminals are exposed to the same surface side of said substrate.

8. A method of producing a semiconductor device according to claim 7, in which said substrate is made of a conductive resin material and said wires are each a conductive wire covered with an insulting film.

9. A method of producing a semiconductor device according to claim 8, in which a binder resin with a conductive material dispersed therein is used as said conductive resin material.

10. A method of producing a semiconductor device according to claim 7, in which an insulative resin material is used as said substrate, and a conductive wire covered with an insulating film and a conductive film in that order is used as said wire.

11. A method of producing a semiconductor device according to claim 7, in which said semiconductor elements and said external connection terminals are connected electrically to each other through conductive wires, after which the wire for connecting each of said semiconductor elements and each of said external connection terminals, the obverse surface of each of said semiconductor elements and the obverse surface of each of said external connection terminals are covered with an insulative resin layer and a conductive metal layer in that order, and the obverse surface of said substrate is covered with an insulative resin material of a predetermined thickness thereby to form a substrate, while at the same time sealing said semiconductor elements, said external connection terminals and said wires with a resin in said substrate thereby to produce a semiconductor device in process.

12. A method of producing a semiconductor device according to any one of claims 7 to 11, in which said external connection terminals each constitute a conductive metal pole placed on the obverse surface of said substrate.

13. A method of producing a semiconductor device according to any one of claims 7 to 11, in which each of said semiconductor elements and each of said external connection terminals are connected electrically to each other through a wire, after which the performance and the like of the resulting connected unit are tested and, in accordance with the result of the test, said semiconductor elements or said external connection terminals are reworked.

14. A method of producing a semiconductor device according to any one of claims 7 to 11, in which a plurality of said semiconductor devices are electrically connected to each other through external connection terminals, respectively, and stacked in the thickness of said substrate.
